(19) United States
(12) Patent Application Publication
(10) Pub. No.: US 2008/0239641 A1
(43) Pub. Date: Oct. 2, 2008

(54) METHOD OF MANUFACTURING ELECTRONIC APPARATUS, ELECTRONIC APPARATUS, AND SUBASSEMBLY PRODUCT

(75) Inventors: Masanori Sato, Koganei-shi (JP); Hiroyuki Minaguchi, Higashimatsuyama-shi (JP); Tomomi Murayama, Nishitama-gun (JP); Satoshi Ooya, Akishima-shi (JP); Naoya Shigenobu, Ome-shi (JP); Ryosuke Saito, Ome-shi (JP); Masataka Tokoro, Tachikawa-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/044,747

(22) Filed: Mar. 7, 2008

(30) Foreign Application Priority Data
Mar. 30, 2007 (JP) 2007093646

(51) Int. Cl. H05K 7/00; B23P 11/00

(52) U.S. Cl. 361/681; 29/428

(57) ABSTRACT

According to one embodiment, an electronic apparatus includes a first housing to which a mounting component is attached, a second housing containing the display, and a hinge portion which rotatably connects the second housing to the first housing. A method of manufacturing the electronic apparatus includes preparing a subassembly product formed by connecting a cover member, which is to form part of the first housing and to which the mounting component is to be mounted, with a mask member, which is to form part of the second housing and is provided with an opening portion to expose a display screen of the display to outside, by the hinge portion, and mounting the mounting component on the cover member through the opening portion of the mask member, in a state where the subassembly product is folded such that the mask member is superposed on the cover member.

### CROSS-REFERENCE TO RELATED APPLICATIONS

This application is based upon and claims the benefit of priority from Japanese Patent Application No. 2007-093646, filed Mar. 30, 2007, the entire contents of which are incorporated herein by reference.

### BACKGROUND

1. Field

One embodiment of the present invention relates to an electronic apparatus in which a display unit is openable/closable with respect to a main body unit, a subassembly product used for manufacturing the electronic apparatus, and a method of manufacturing the electronic apparatus.

2. Description of the Related Art

Electronic apparatuses such as portable computers have a main body unit equipped with a circuit board, and a display unit equipped with a display. A hinge portion is provided between the main body unit and the display unit. The hinge portion supports the display unit such that the display unit is rotatable with respect to the main body unit.

The main body unit has a first housing. The first housing is formed to have a box shape having a top wall, a peripheral wall, and a bottom wall. The first housing is divided into a base member including the bottom wall, and a first cover member including the top wall. On the other hand, the display unit has a second housing. The second housing is formed to have a box shape including a front wall, a peripheral wall, and a back wall. The second housing is divided into a mask member including the front wall, and a second cover member including the back wall. The mask member has a large opening portion which exposes a display screen of the display to the outside.

The hinge portion has a one end portion which is fixed onto the first cover member, and the other end portion which is fixed onto the second cover member. The hinge portion connects the second cover member to the first cover member.

“Notebook PC Full-Line Catalogue (Qosmio/dynabook/dynabook SS) 2007 Spring Model” (published by Kabushiki Kaisha Toshiba PC & Network, January 2007, p.4) discloses an electronic apparatus in which an opening portion of the mask member is larger than the outer shape of the keyboard. The electronic apparatus has a large display screen of 17-inch wide. Therefore, the mask member is provided with the large opening portion corresponding to its display screen.

Further, Jpn. Pat. Appln. KOKAI Pub. No. 2005-100173 discloses an electronic apparatus in which an operating panel is provided in a side space of a keyboard.

When an electronic apparatus having a first housing and a second housing as described above is assembled, first, a subassembly product (that is, a cover assembly) which is formed by connecting the second cover member to the first cover member by the hinge portion. The subassembly product is assembled in, for example, a separate location, and supplied in a state of being folded such that the second cover member is superposed on the first cover member.

In assembly of the electronic apparatus, the second cover member is raised with respect to the first cover member, and the raised second cover member is laid on an assembly table. Then, a display is mounted on the laid second cover member. Next, a mask member is engaged to the second cover member equipped with the display. Thereby, a display unit is assembled.

After the display unit is assembled, the base member of the main body unit is laid again on the assembly table. Then, a keyboard as a mounting component is mounted on the top wall of the first cover member, in the state where the display unit is raised with respect to the main body unit. Lastly, the display unit is closed with respect to the main body unit, and thereby assembly of the electronic apparatus is finished.

The electronic apparatus as described above requires troublesome steps of raising, closing, and laying again the members of the electronic apparatus during assembly thereof.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to an embodiment of the invention;

FIG. 2 is an exemplary perspective view of a subassembly product according to the embodiment of the invention;

FIG. 3 is an exemplary enlarged perspective view of a part of the subassembly product illustrated in FIG. 2;

FIG. 4 is an exemplary perspective view of the subassembly product according to the embodiment of the present invention, with a hinge portion exploded;

FIG. 5 is an exemplary perspective view of an area enclosed by line F5 in the subassembly product illustrated in FIG. 4;

FIG. 6 is an exemplary perspective view of an area enclosed by line F6 in the subassembly product illustrated in FIG. 4;

FIG. 7 is an exemplary perspective view of a second cover according to the embodiment of the invention;

FIG. 8 is an exemplary cross-sectional view of a display unit according to the embodiment of the invention;

FIG. 9 is an exemplary perspective view illustrating a step of engaging a base member with the subassembly product according to the embodiment of the invention;

FIG. 10 is an exemplary perspective view illustrating a step of mounting a touch pad according to the embodiment of the invention;

FIG. 11 is an exemplary perspective view illustrating a step of mounting a keyboard according to the embodiment of the invention;

FIG. 12 is an exemplary cross-sectional view illustrating the step of mounting the keyboard according to the embodiment of the invention;

FIG. 13 is an exemplary perspective view illustrating a step of attaching a display according to the embodiment of the invention;

FIG. 14 is an exemplary perspective view illustrating a step of attaching the second cover member according to the embodiment of the invention; and

FIG. 15 is an exemplary perspective view illustrating an assembled portable computer according to the embodiment of the invention.

### DETAILED DESCRIPTION

Various embodiments according to the invention will be described hereinafter with reference to the accompanying drawings. In general, according to one embodiment of the invention, a method of manufacturing an electronic apparatus includes preparing a subassembly product. The electronic apparatus includes a first housing to which a mounting component is attached, a second housing containing a display, and a hinge portion which rotatably connects the second housing to the first housing. The subassembly product is formed by connecting a cover member, which is to form part of the first housing and to which the mounting component is to be mounted, with a mask member, which is to form part of the second housing and is provided with an opening portion to expose a display screen of the display to outside, by the hinge portion. The mounting component is mounted on the cover member through the opening portion of the mask member, in a state where the subassembly product is folded such that the mask member is superposed on the cover member.

According to one embodiment of the invention, an electronic apparatus according to the invention comprises: a first housing; a second housing; a hinge portion which rotatably connects the second housing to the first housing; a mounting component attached to the first housing; and a display which is contained in the second housing and includes a display screen. The first housing includes a first cover member to which the mounting component is attached. The second housing includes a mask member provided with an opening portion which exposes the display screen to outside, and a second cover member which faces the display from a side distant from the mask member and is engaged with the mask member. The hinge portion connects the mask member to the first cover member. The display and the second cover member are detachable from the mask member. The opening portion of the mask member is larger than an outer shape of the mounting component.

According to one embodiment of the invention, a subassembly product forms part of an electronic apparatus, the apparatus including a first housing and a second housing which contains a display, the display including a display screen. The subassembly product comprises: a cover member which is to form part of the first housing and is provided with a placing portion, to which a mounting component is to be placed; a mask member which is to form part of the second housing, includes an opening portion to expose the display screen to outside, and includes an area to which the display is to be mounted, the area being opened to outside; and a hinge portion which rotatably connects the mask member to the cover member. A whole area of the placing portion is exposed to outside through the opening portion of the mask member, in a state where the mask member is superposed on the cover member.

An embodiment of the present invention is explained with respect to drawings in which an embodiment of the present invention is applied to a portable computer.

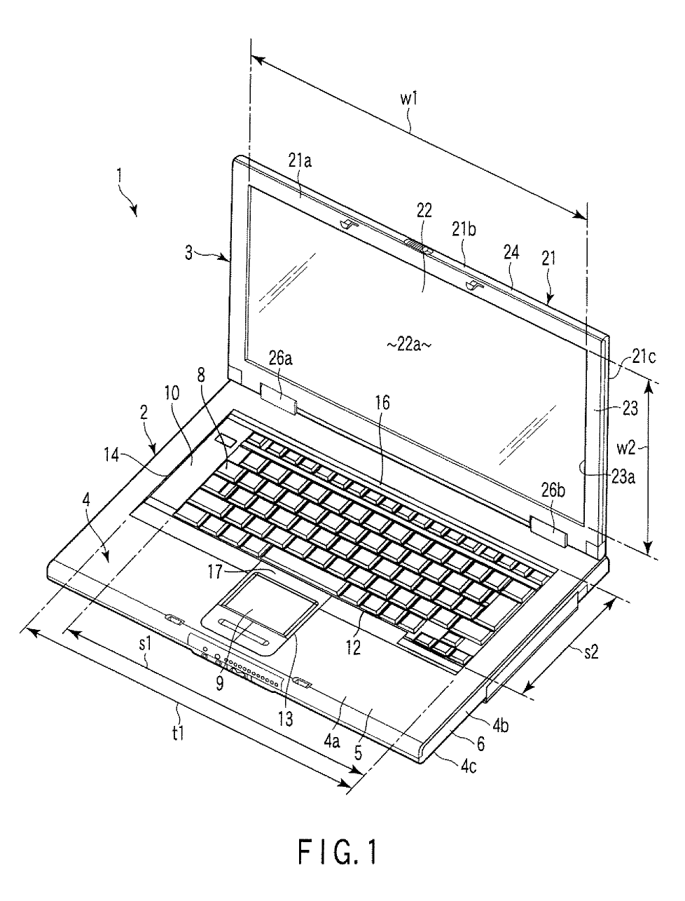

FIGS. 1 to 15 illustrate a portable computer 1 serving as an electronic apparatus according to an embodiment of the present invention. As illustrated in FIG. 1, the portable computer 1 comprises a main body unit 2 and a display unit 3.

As illustrated in FIG. 1, the main body unit 2 has a first housing 4 having a box shape. The first housing 4 has a top wall 4a, a peripheral wall 4b, and a bottom wall 4c. The first housing 4 has a first cover member 5, and a base member 6. The first cover member 5 includes the top wall 4a and part of the peripheral wall 4b, and forms part of the first housing 4. The base member 6 includes the bottom wall 4c and part of the peripheral wall 4b, and forms part of the first housing 4. The first cover member 5 is engaged with the base member 6, and detachably supported by the base member 6.

A keyboard 8, a touch pad 9, and a button unit 10 are mounted on the top wall 4a of the first cover member 5. Each of the keyboard 8 and the touch pad 9 is an example of a mounting component (i.e. housing mounting component). The top wall 4a is provided with a keyboard placing portion 12 in which the keyboard 8 is mounted, a touch pad placing portion 13 in which the touch pad 9 is mounted, and a button unit placing portion 14 in which the button unit 10 is mounted. Each of the placing portions 12, 13 is an example of a placing portion of the invention.

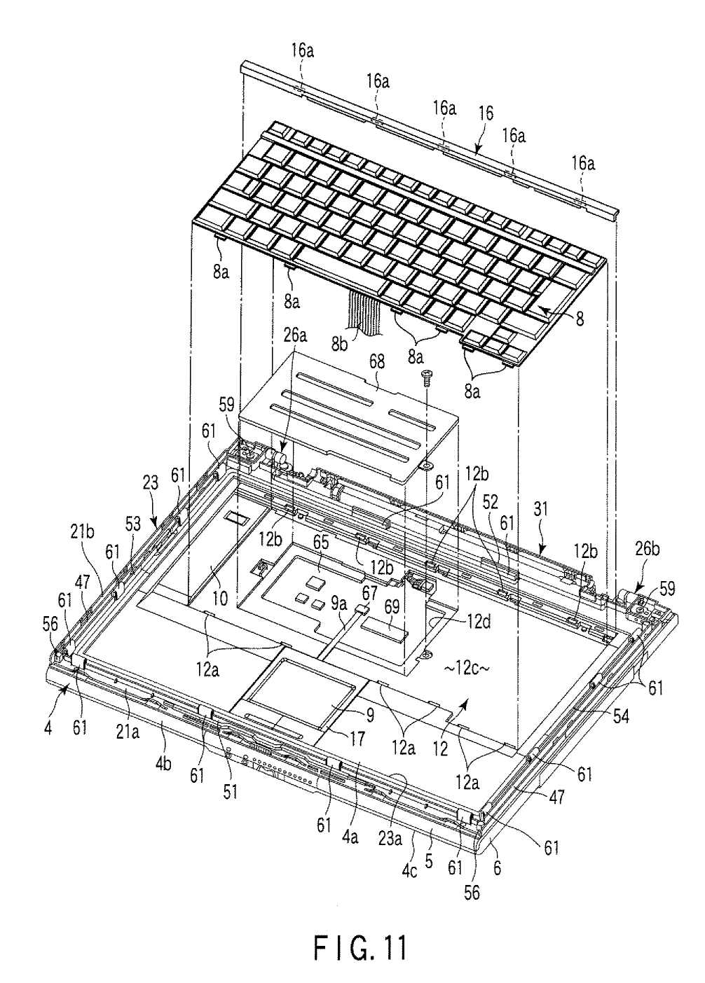

The portable computer 1 has a keyboard holder 16 which fixes the keyboard 8 onto the keyboard placing portion 12. As illustrated in FIG. 11, engaging claws 8a are provided on one end portion of the keyboard 8. On the other hand, the keyboard placing portion 12 is provided with engagement holes 12a facing the engaging claws 8 of the keyboard 8. When the engaging claws 8a of the keyboard 8 are inserted into the respective engagement holes 12a, one end portion of the keyboard 8 is supported by the keyboard placing portion 12.

The keyboard holder 16 has engaging projections 16a. Engagement holes 12b with which the engaging projections 16a of the keyboard holder 16 engage are provided in an edge portion of the keyboard placing portion 12, which is located opposite to the end portion provided with the engagement holes 12a. The keyboard holder 16 is detachably attached to the edge portion of the keyboard placing portion 12, and supports the other end portion of the keyboard 8. Thereby, the both end portions of the keyboard 8 are fixed onto the keyboard placing portion 12. The keyboard 8 may be fixed by fixing members such as screws, instead of the keyboard holder 16.

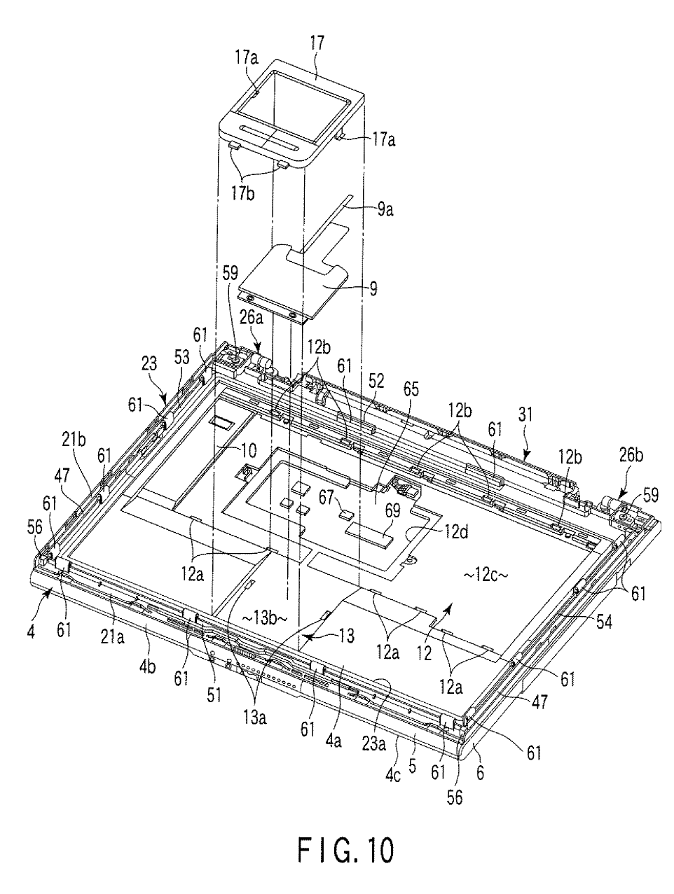

The portable computer 1 has a touch pad frame 17 which fixes the touch pad 9 onto the touch pad placing portion 13. As illustrated in FIG. 10, the touch pad frame 17 has first and second engaging claws 17a and 17b. The touch pad placing portion 13 is provided with first engagement holes 13a facing the first engaging claws 17a, and second engagement holes (not shown) facing the second engaging claws 17b.

The touch pad frame 17 is attached to the touch pad placing portion 13 such that the touch pad 9 is held between the touch pad frame 17 and the touch pad placing portion 13. When the first and second engaging claws 17a and 17b are engaged with the first engagement holes 13a and the second engagement holes 13b, respectively, the touch pad 9 and the touch pad frame 17 are fixed onto the touch pad placing portion 13.

As illustrated in FIG. 1, the display unit 3 has a second housing 21 having a box shape, and a display 22 contained in the second housing 21. Examples of the display 22 are a liquid crystal display, a plasma display, an organic electroluminescent display, and a surface-conduction electron-emitter display. The display 22 has a display screen 22a.

The second housing 21 has a front wall 21a, a peripheral wall 21b, and a back wall 21c. The second housing 21 has a mask member 23, and a second cover member 24. The second cover member 24 is an example of another cover member. The mask member 23 includes the front wall 21a and part of the peripheral wall 21b, and forms part of the second housing 21. The second cover member 24 includes the back wall 21c and part of the peripheral wall 21b, and forms part of the second housing 21. The second cover member 24 is opposed to the display 22 from the side distant from the mask member 23, engaged with the mask member 23, and detachably supported by the mask member 23.

A large opening portion 23a is formed in the front wall 21a of the mask member 23. The opening portion 23a is opposed to the display 22, and exposes the display screen 22a of the display 22 to the outside of the second housing 21. One example of the size of the opening portion 23a of the mask member 23 is larger than the total size of the outer shape of keyboard placing portion 12 and the outer shape of the button unit placing portion 14. Specifically, the size of the opening portion 23a is larger than the outer shape of the keyboard 8, and larger than the outer shape of the keyboard holder 16.

More specifically, as illustrated in FIG. 1, a longitudinal width w1 of the opening portion 23a is larger than a longitudinal width s1 of the keyboard 8, and larger than a longitudinal width t1 of the keyboard holder 16. A length w2 of the opening portion 23a in a direction perpendicular to the longitudinal direction thereof is larger than a total length s2 of the keyboard 8 and the keyboard holder 16 in a direction perpendicular to the longitudinal direction of the keyboard 8.

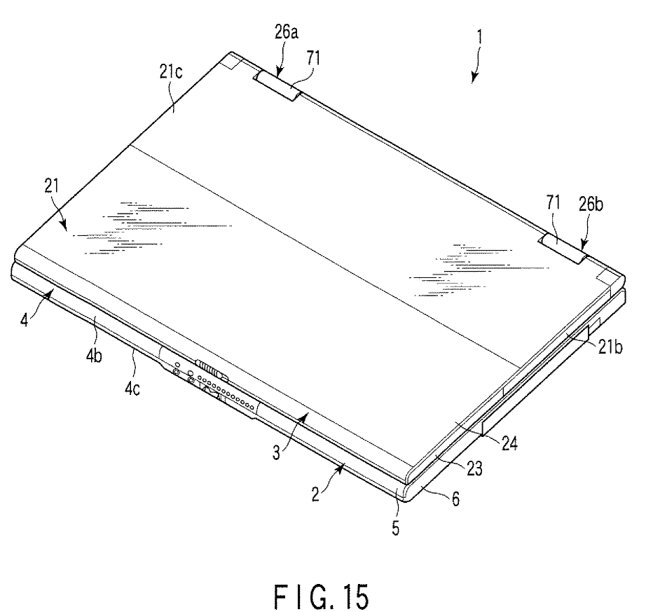

A pair of hinge portions 26a and 26b are provided between the first housing 4 and the second housing 21. The hinge portions 26a and 26b support the second housing 21 such that the second housing 21 is rotatable with respect to the first housing 4. Therefore, the display unit 3 is rotatable between a closed position (refer to FIG. 15), in which the display unit 3 is closed to cover the top wall 4a of the main body unit 2 from above, and an open position (refer to FIG. 1) in which the display unit 3 is raised to expose the top wall 4a.

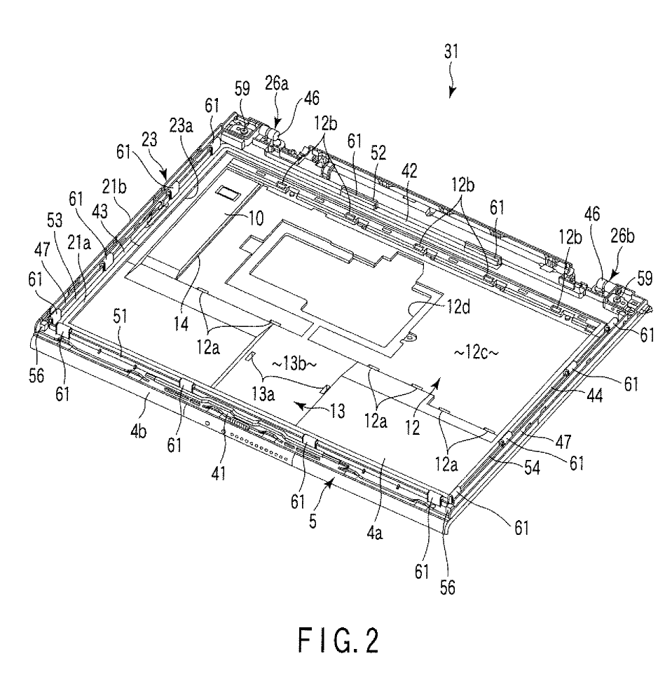

Next, a subassembly product 31 which is called a “cover assembly” is explained with reference to FIGS. 2 to 6. The subassembly product 31 is a component which forms part of the portable computer 1.

As illustrated in FIG. 2, the subassembly product 31 according to the embodiment includes the first cover member 5, the mask member 23, and the hinge portions 26a and 26b. Each of the hinge portions 26a and 26b has one end portion fixed onto the mask member 23, and the other end portion fixed onto the first cover member 5, and rotatably connects the mask member 23 to the first cover member 5. Thereby, the subassembly product 31 is connected and integrated.

As described above, the first cover member 5 is provided with the keyboard placing portion 12, the touch pad placing portion 13, and the button unit placing portion 14. The button unit 10 is attached to the button unit placing portion 14. The keyboard placing portion 12 has a bottom wall 12c. An opening portion 12d is provided in the bottom wall 12c. The touch pad placing portion 13 has a bottom wall 13b.

The mask member 23 includes the front wall 21a and part of the peripheral wall 21b of the second housing 21 as described above, and is opened to the outside in the direction facing the back wall 21c. Specifically, it can be said that an area of the mask member 23 in which the display 22 is mounted is opened to the outside. Thereby, a whole area of the keyboard placing portion 12 is exposed to the outside through the opening portion 23a of the mask member 23, in the state where the mask member 23 is superposed on the first cover member 5.

As illustrated in FIG. 2, the mask member 23 has four edge portions 41, 42, 43 and 44 which form a frame of the mask member 23 in cooperation. Specifically, the mask member 23 has a first edge portion 41 which is located uppermost when the display unit 3 is raised with respect to the main body unit 2, a second edge portion 42 which is located lowermost when the display unit 3 is raised with respect to the main body unit 2, and third and fourth edge portions 43 and 44 which extend between the first and second edge portions 41 and 42 on the left and the right sides of the opening portion 23a, respectively.

Each of the hinge portions 26a and 26b has a hinge shaft 46 and a sheet-metal member 47. The sheet-metal member 47 is an example of a support member. The hinge shaft 46 is provided between the first housing 4 and the second housing 21. Specifically, the first edge portion 41 is an edge portion most distant from the hinge shaft 46 in the mask member 23.

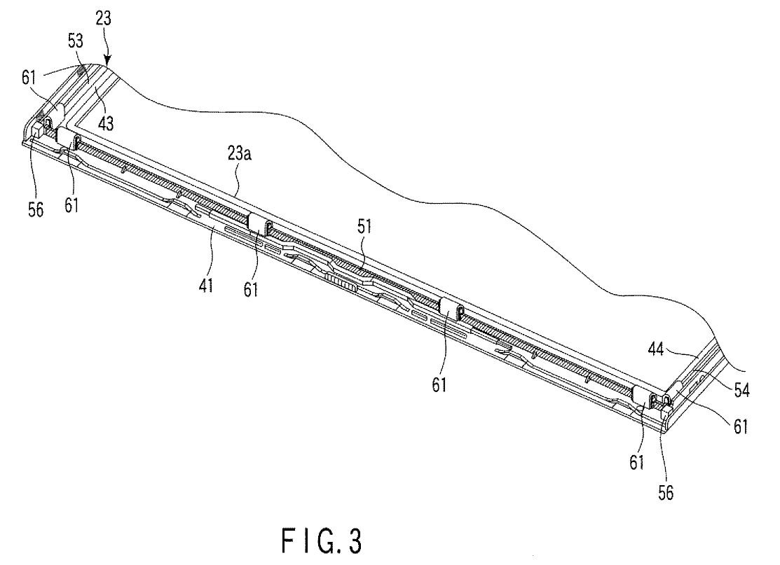

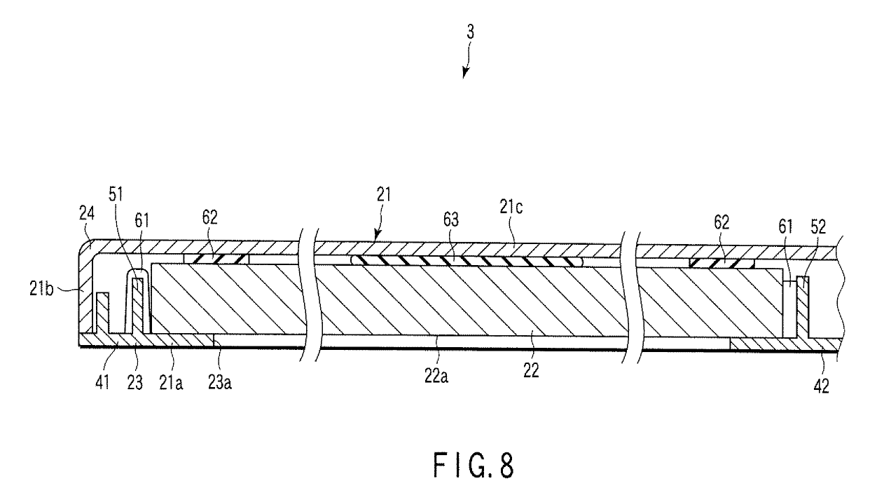

As illustrated in FIG. 3, the first edge portion 41 is provided with a first rib 51. For explanation, the first rib 51 is hatched in FIG. 3. The first rib 51 stands up in the thickness direction (the vertical direction in FIG. 8) of the display unit 3, and extends from one end portion to the other end portion of the first edge portion 41 along the axial direction of the hinge shaft 46 (that is, the direction extending from the third edge portion 43 toward the fourth edge portion 44, hereinafter referred to as “the first direction”).

As illustrated in FIG. 2, the second edge portion 42 is provided with a second rib 52. The second rib 52 stands up in the thickness direction of the display unit 3, and extends along the first direction. The third edge portion 43 is provided with a third rib 53. The fourth edge portion 44 is provided with a fourth rib 54.

The third and fourth ribs 53 and 54 stand in the thickness direction of the display unit 3, and extend from one end portion to the other end portion of the third edge portion 43 or the fourth edge portion 44, along a direction perpendicular to the axial direction of the hinge shaft 46 (that is, a direction extending from the second edge portion 42 toward the first edge portion 41, hereinafter referred to as “the second direction”).

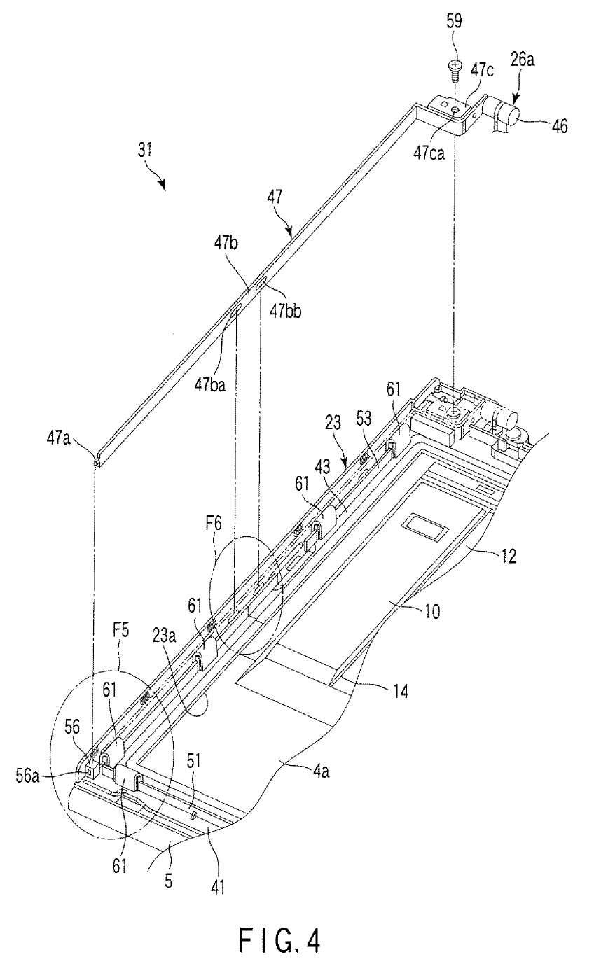

FIG. 4 illustrates one hinge portion 26a in detail. One end of the hinge shaft 46 is fixed onto the first cover member 5 by a fixing mechanism (not shown). The other end of the hinge shaft 46 is connected to the sheet-metal member 47. The sheet-metal member 47 extends into the second housing 21, and is attached to the mask member 23. The other hinge portion 26b has the same structure as that of the hinge portion 26a.

The sheet-metal member 47 extends from one end portion to the other end portion of the third edge portion 43 or the fourth edge portion 44, along the second direction. A distal end portion 47a, a center portion 47b, and a proximal end portion 47c of the sheet-metal member 47 are fixed onto the mask member 23.

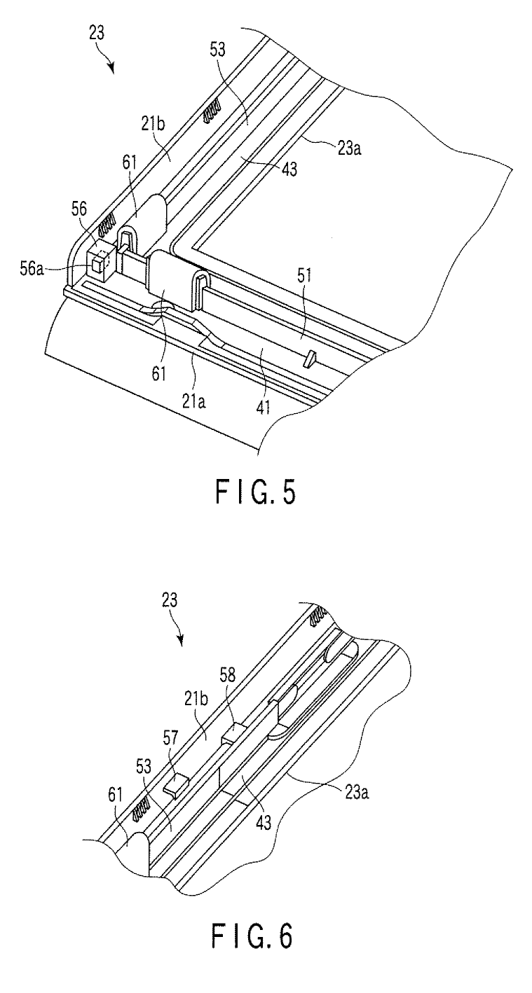

More specifically, as illustrated in FIG. 4, the distal end portion 47a of the sheet-metal member 47 is tapered to have a projection shape. As illustrated in FIG. 5, an engagement member 56 is provided in an end portion of the third edge portion 43. An engagement hole 56a opposed to the distal end portion 47a of the sheet-metal member 47 is opened in the engagement member 56. When the distal end portion 47a of the sheet-metal member 47 is inserted into the engagement hole 56a, the distal end portion 47a of the sheet-metal member 47 is fixed to the mask member 23.

As illustrated in FIG. 4, two opening portions 47ba and 47bb are provided in the center portion 47b of the sheet-metal member 47. As illustrated in FIG. 6, an engaging claw 57 projects from a wall portion forming the peripheral wall 21b toward one opening portion 47ba of the sheet-metal member 47. Further, an engaging claw 58 projects from the third rib 53 toward the other opening portion 47bb of the sheet-metal member 47. When the opening portions 47ba and 47bb of the sheet-metal member 47 are engaged with the engaging claws 57 and 58, respectively, the center portion 47b of the sheet-metal member 47 is fixed to the mask member 23.

As illustrated in FIG. 4, a screw insertion hole 47ca is provided in the proximal end portion 47c of the sheet-metal member 47. The mask member 23 is provided with a boss (not shown) which is opposed to the screw insertion hole 47ca and has a screw hole. When a screw 59 which is inserted through the screw insertion hole 47ca is screwed into the screw hole of the boss, the proximal end portion 47c of the sheet-metal member 47 is fixed to the mask member 23. Since the largest force acts on the proximal end portion 47c in the sheet-metal member 47, the proximal end portion 47c is firmly secured to the mask member 23 by using the screw 59.

As illustrated in FIG. 3, the engagement member 56, with which the distal end portion 47a of the sheet-metal member 47 of the hinge portion 26a is engaged, is located adjacent to one end of the first rib 51. The engagement member 56, with which the distal end portion 47a of the sheet-metal member 47 of the hinge portion 26b is engaged, is located adjacent to the other end of the first rib 51. The first rib 51 extends between the sheet-metal members 47 of a pair of the hinge portions 26a and 26b that are provided distant from each other in the first direction. Specifically, the sheet-metal members 47 of the hinge portions 26a and 26b and the first rib 51 surround the opening portion 23a in cooperation from three directions, and enhance stiffness of the mask member 23. Further, the second to fourth ribs 52, 53 and 54 enhance the stiffness of the mask member 23.

As illustrated in FIG. 2, the mask member 23 is provided with a plurality of first elastic members 61. An example of the first elastic members 61 is a rubber member. The first elastic members 61 are spaced from one another and arranged in regions surrounding the display 22. The first elastic members 61 are attached to the first to fourth ribs 51, 52, 53, and 54.

The distance between the first elastic members 61 attached to the first rib 51 and the first elastic members 61 attached to the second rib 52 is almost the same as or slightly smaller than the length of the display 22 along the second direction. The distance between the first elastic member 61 attached to the third rib 53 and the first elastic members 61 attached to the fourth rib 54 is almost the same as or slightly smaller than the width of the display 22 along the first direction.

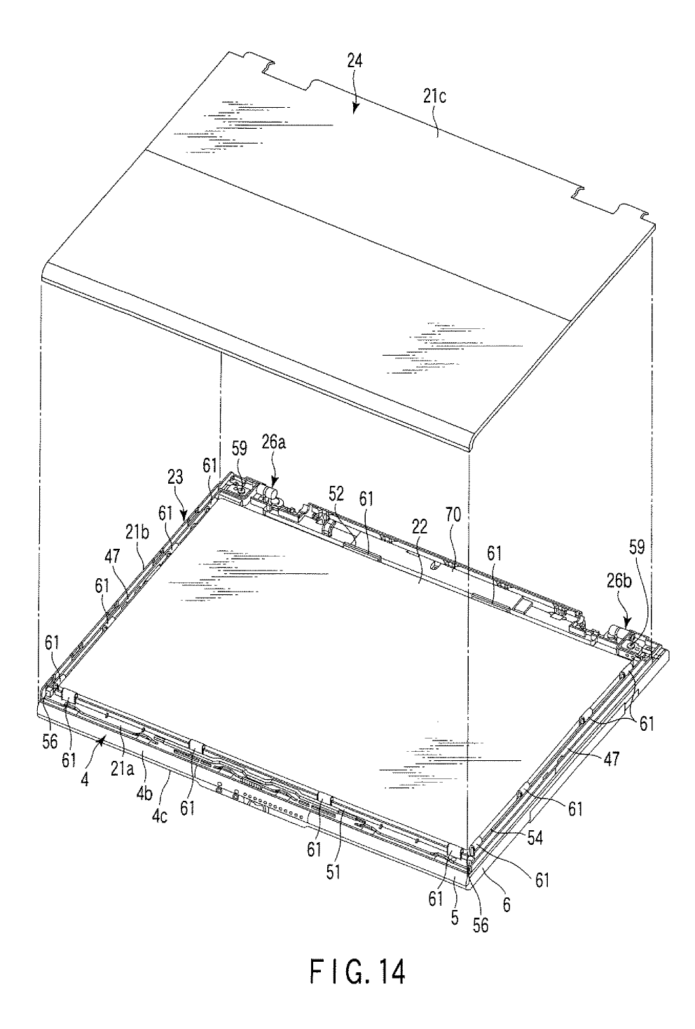

As illustrated in FIG. 14, when the display 22 is placed on the mask member 23, the display 22 is surrounded by the first elastic members 61 attached to the first to fourth ribs 51, 52, 53 and 54. The first elastic members 61 support the display 22 in cooperation from four directions. In other words, the display 22 is fitted in a region surrounded by the first elastic members 61. Thereby, the position of the display 22 along the first and second directions is fixed. The display 22 is detachable from the mask member 23.

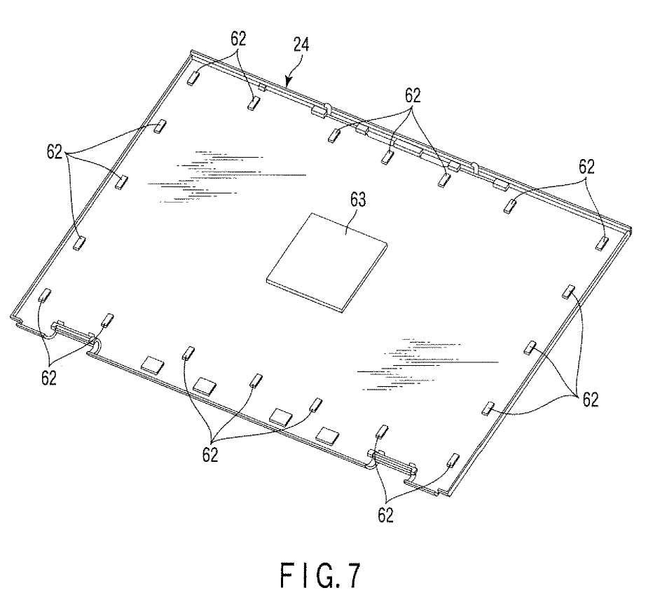

As illustrated in FIG. 7, second and third elastic members 62 and 63 are attached to a surface of the second cover member 24 opposed to the display 22. Specifically, the second elastic members 62 are attached to a region opposed to the edge portion of the display 22. The third elastic member 63 is attached to a region opposed to the central portion of the display 22. As illustrated in FIG. 8, when the second cover member 24 is engaged with the mask member 23, the second and third elastic members 62 and 63 are interposed between the display 22 and the second cover member 24.

An example of the second elastic members 62 is rubber members. An example of the third elastic member 63 is a sponge member. The second elastic members 62 are formed of a material having a larger coefficient of elasticity than that of the third elastic member 63. In other words, the second elastic member 62 is formed of a material which is less deformable and harder than the third elastic member 63.

The second elastic members 62 are provided to position the display 22 along the thickness direction of the display unit 3. Since the second elastic members 62 which are resistant to deformation are opposed to the edge portion of the display 22, the display 22 is prevented from wobbling.

The thickness of the third elastic member 63 is set larger than the thickness of the second elastic member 62. When the second cover member 24 is engaged with the mask member 23, the third elastic member 63 is compressed to almost the same thickness as that of the second elastic members 62. The third elastic member 63 applies pressing force to the display 22 toward the mask member 23.

The second elastic members 62 have parts tolerances, and thus are slightly different from one another in thickness. The third elastic member 63 presses the display 22 toward the mask member 23, and thereby influence of parts tolerances of the second elastic members 62 is reduced, and wobbling of the display 22 is further suppressed. The second and third elastic members 62 and 63 may be attached to the back surface of the display 22, instead of the second cover member 24.

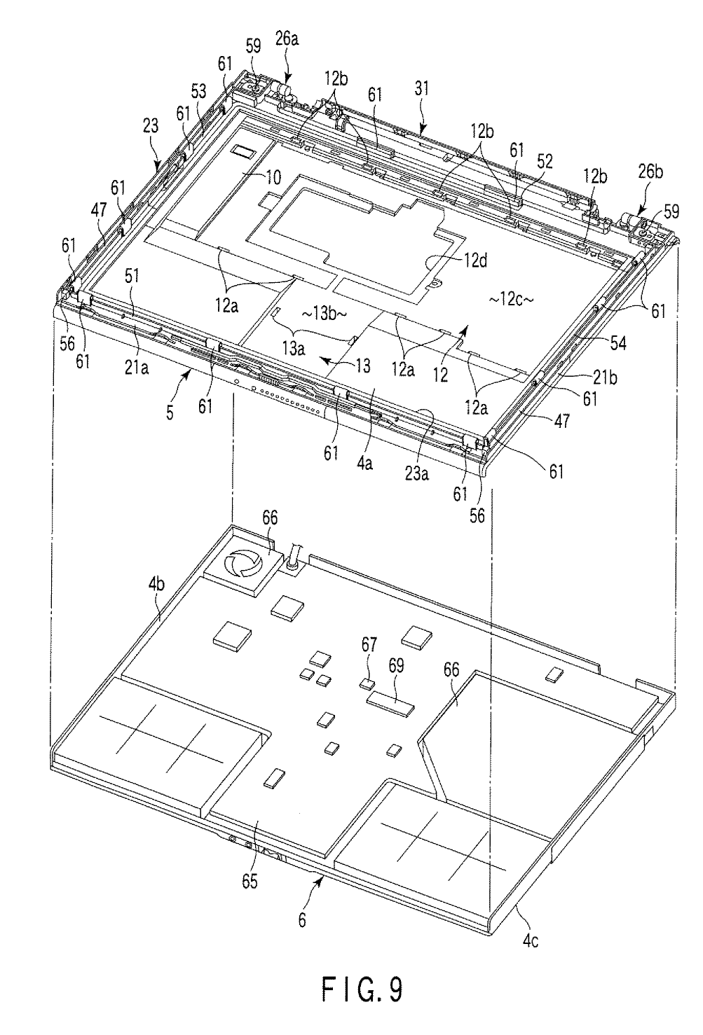

Next, an example of a method of manufacturing the portable computer 1 is explained with reference to FIGS. 9 to 15.

First, the base member 6, the second cover member 24, and the subassembly product 31 are prepared. The subassembly product 31 is assembled in, for example, a separate location, and prepared in the state where the mask member 23 is folded to be superposed on the first cover member 5, that is, in the state where the mask member 23 is closed with respect to the first cover member 5.

As illustrated in FIG. 9, a circuit board 65 and a unit 66 are mounted on the prepared base member 6. Examples of the unit 66 are a cooling fan and an optical disk drive. After the circuit board 65 and the unit 66 are mounted on the base member 6, the subassembly product 31 assembled in advance is engaged with the base member 6 from above. Specifically, the first cover member 5 of the subassembly product 31 is engaged with the base member 6, and thereby the first housing 4 is formed. In the step of engaging the base member 6 with the subassembly product 31, the subassembly product 31 is kept in the state where the mask member 23 is folded to be superposed on the first cover member 5.

As illustrated in FIG. 10, after the subassembly product 31 is engaged with the base member 6, the touch pad 9 and the touch pad frame 17 are attached. In the step of attaching the touch pad 9 and the like, the subassembly product 31 is kept in the state where the mask member 23 is folded to be superposed on the first cover member 5. The touch pad 9 and the touch pad frame 7 are mounted on the touch pad placing portion 13 through the opening portion 23 of the mask member 23a.

Specifically, first, the touch pad 9 is placed on the touch pad placing portion 13. Before or after placing of the touch pad 9, a cable 9a of the touch pad 9 is inserted into a connector 67 mounted on the circuit board 65. Thereby, the touch pad 9 is electrically connected to the circuit board 65.

After the touch pad 9 is placed, the touch pad frame 17 is attached onto the touch pad 9. Specifically, the second engaging claws 17b of the touch pad frame 17 are engaged with corresponding engagement holes (not shown), and the first engaging claws 17a are engaged with the engagement holes 13a. Thereby, the touch pad 9 and the touch pad frame 17 are fixed onto the touch pad placing portion 13.

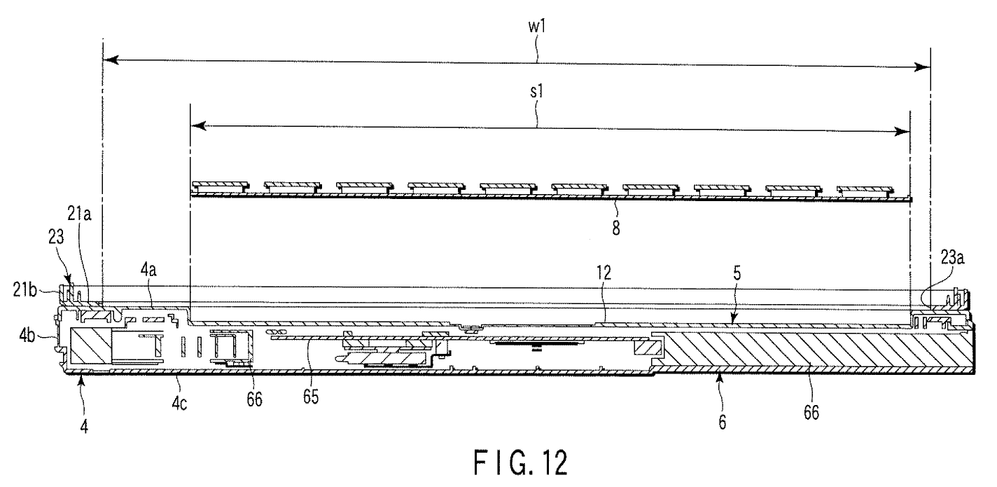

As illustrated in FIG. 11, after the touch pad 9 is attached, the keyboard 8, the keyboard holder 16, and a reinforcing member 68 are attached. In the step of attaching the keyboard 8 and the like, the subassembly product 31 is kept in the state where the mask member 23 is folded to be superposed on the first cover member 5. As illustrated in FIGS. 11 and 12, the keyboard 8, the keyboard holder 16, and the reinforcing member 68 are mounted on the first cover member 5 through the opening portion 23a of the mask member 23.

Specifically, a cable 8b of the keyboard 8 is inserted into a connector 69 mounted on the circuit board 65. Thereby, the keyboard 8 is electrically connected to the circuit board 65. After the cable 8b is connected to the connector 69, the reinforcing member 68 is attached to the opening portion 12d of the keyboard placing portion 12. The reinforcing member 68 is formed of sheet metal or the like, and reinforces the bottom wail 12c of the keyboard placing portion 12.

Then, the keyboard 8 is placed on the reinforcing member 68 and the bottom wall 12c. Claws 8a of the keyboard 8 are inserted into the engagement holes 12a, and thereby one end portion of the keyboard 8 is supported. Further, the keyboard holder 16 is attached, and thereby the other end portion of the keyboard 8 is supported.

As described above, the steps of mounting the keyboard 8, the touch pad 9, and components around them are finished.

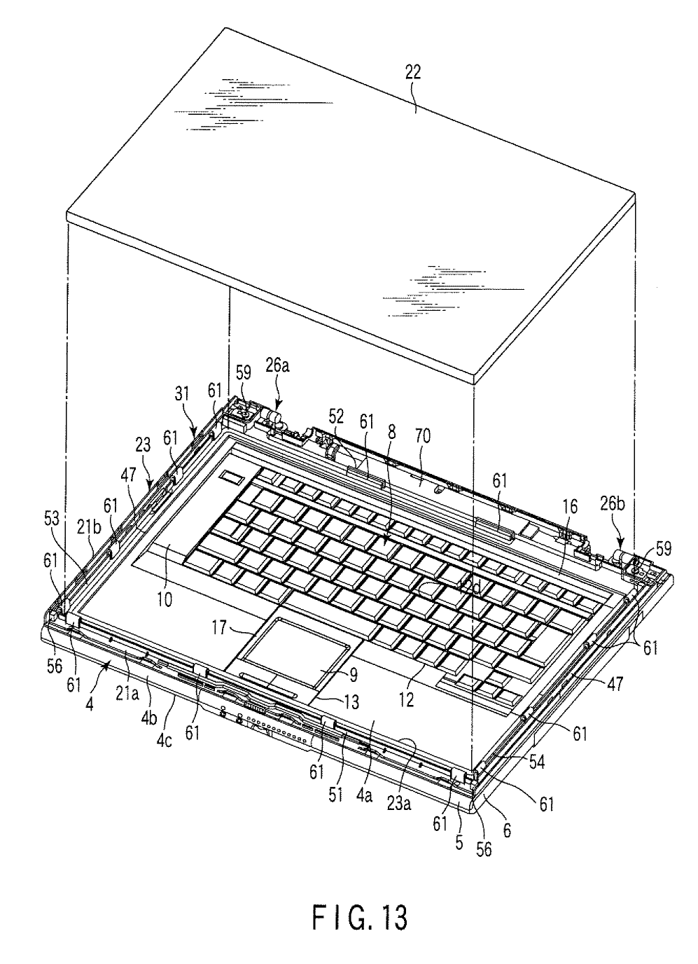

As illustrated in FIG. 13, after the keyboard 8 is mounted on the first cover member 5, the display 22 is mounted on the mask member 23. The display 22 is mounted on the mask member 23 independently of the second cover member 24. Specifically, when the display member 22 is fitted in the region surrounded by the first elastic members 61, the display 22 is supported by the first elastic members 61 from four directions and the position thereof is fixed. Before or after placing the display 22, a cable (not shown) of the display 22 is connected to an inverter 70. In the step of mounting the display 22, the subassembly product 31 is kept in the state where the mask member 23 is folded to be superposed on the first cover member 5.

As illustrated in FIG. 14, the second cover member 24 is engaged with the mask member 23 on which the display 22 has been mounted. In the step of engaging the second cover 24 with the mask member 23, the subassembly product 31 is kept in the state where the mask member 23 is folded to be superposed on the first cover member 5. When the second cover member 24 is engaged with the mask member 23, the second and third elastic members 62 and 63 and the mask member 23 hold the display 22 therebetween, and retain the display 22. Thereby, the position of the display 22 in the thickness direction of the display unit 3 is fixed.

The display 22 may be fixed by using fixing members such as screws. In the embodiment, the display 22 is held by the first to third elastic members 61, 62 and 63, without using fixing members such as screws to fix the display 22.

Lastly, a step of mounting hinge covers 71 is performed, and thereby the portable computer 1 is assembled as illustrated in FIG. 15.

According to the portable computer 1 having the above structure, it is possible to apply a method of manufacturing the portable computer 1 with improved assemblability. Specifically, since the first cover member 5 and the mask member 23 are connected by the hinge portions 26a and 26b, and the display 22 and the second cover member 24 are detachable with respect to the mask member 23, the keyboard placing portion 12 is exposed to the outside through the opening portion 23a of the mask member 23, even in the state where the mask member 23 is superposed on the first cover member 5.

Since the opening portion 23a of the mask member 23 is formed larger than the outer shape of the keyboard 8, the keyboard 8 can be mounted on the keyboard placing portion 12 through the opening portion 23a of the mask member 23. Specifically, the keyboard 8 can be attached to the first cover member 5, without raising the mask member 23 with respect to the first cover member 5. The mounting work can be simplified since it is unnecessary to raise the mask member 23 in the step of mounting the keyboard 8, and thus assemblability of the portable computer 1 is improved.

In the same manner, since the keyboard holder 16 can be attached to the first cover member 5 through the opening portion 23a of the mask member 23, it is unnecessary to raise the mask member 23 for mounting the keyboard holder 16. The touch pad 9 can be mounted on the first cover member 5 through the opening portion 23a of the mask member 23, and it is unnecessary to raise the mask member 23 for mounting the touch pad 9. These points improve the assemblability of the portable computer 1.

Since the display 22 is mounted after the keyboard 8 is mounted on the first cover member 5, the display 22 does not become an obstacle in the step of mounting the keyboard 8. Since the display 22 is mounted on the mask member 23, it is unnecessary to raise the mask member 23 for mounting the display 22. This contributes to improvement in assemblability of the portable computer 1. Further, since the display 22 is mounted in the state where the mask member 23 is superposed on the first cover member 5, the mounting direction of the display 22 can be aligned with the mounting direction of the keyboard 8. Aligning the mounting directions of a plurality of units contributes to improvement in assemblability of the portable computer 1, since the assembly process can be simplified.

Since the second cover member 24 is engaged with the mask member 23 in the state where the mask member 23 is superposed on the first cover member 5, the mounting direction of the second cover member 24 can be aligned with the mounting direction of the keyboard 8.

According to the embodiment, the portable computer 1 is assembled by superposing the circuit board 65, the subassembly product 31, the touch pad 9, the touch pad frame 17, the keyboard 8, the keyboard holder 16, the display 22, and the second cover member 24 on the base member 6 in succession. Specifically, the mounting directions of main components 65, 31, 9, 17, 8, 16, 22 and 24 forming the portable computer 1 are unified to the same direction. Therefore, the worker can successively stack the main components 65, 31, 9, 17, 8, 16, 22 and 24 in a fixed direction, and very high workability is achieved.

Further, the mounting direction is a vertical downward direction. The worker can stack up the main components 65, 31, 9, 17, 8, 16, 22 and 24 upward. Therefore, the workability is further improved, and the required workspace is relatively small. Further, the assembly work is simplified, and thus the invention contributes to reduction in mistakes in work. Further, since the mounting directions of the main components are unified to a specific direction, the invention has an advantage in automation of assembly.

It is considered that the subassembly product 31 is assembled in a separate location, for example, and supplied in the folded state such that the mask member 23 is superposed on the first cover member 5. According to the portable computer 1 of the embodiment, it is possible to assemble the portable computer 1 in the state where the mask member 23 is kept closed, without raising the mask member 23 with respect to the first cover member 5 once.

Specifically, it is never necessary to raise the mask member 23, in mounting the touch pad 9, the touch pad frame 17, the keyboard 8, the keyboard holder 16, the display 22, and the second cover member 24 as described above. Specifically, the portable computer 1 can be assembled, without raising, closing, replacing, or rotating the mask member 23 and the second cover member 24. This contributes to improvement in assemblability of the portable computer 1.

Further, since it is unnecessary to raise the mask member 23 and the second cover member 24, damage to the components is suppressed, and the quality of the portable computer 1 is improved.

Since the hinge portions 26a and 26b are connected to the mask member 23, bending moment is applied to the mask member 23 when the display unit 3 is rotated. Generally, the mask member 23 has stiffness lower than that of the second cover member 24, for example, since it has the large opening portion 23a. However, in the portable computer 1 according to the embodiment, the sheet-metal members 47 of the hinge portions 26a and 26b extend from one end portion to the other end portion of the mask member 23, along a direction perpendicular to the axial direction of the hinge shafts 46. Therefore, most of the bending moment applied to the mask member 23 can be received by the sheet-metal members 47, and it is possible to prevent breakage of the mask member 23.

Further, the first rib 51 is provided between the sheet-metal members 47 of the hinge portions 26a and 26b, in the edge portion 41 which is most distant from the hinge shafts 46 in the mask member 23. Providing the first rib 51 enhances the stiffness of the edge portion 41, and it is possible to prevent breakage of the mask member 23. Since the first rib 51 extends between the sheet-metal members 47 of the hinge portions 26a and 26b, the first rib 51 and the two sheet-metal members 47 further enhance the stiffness of the mask member 23 in cooperation.

Since the sheet-metal members 47 are attached by insertion into the engagement members 56 or engagement by the engaging claws 57 and 58, screwing steps or the like can be reduced, and thereby assemblability can be improved.

The display 22 may be screwed to the sheet-metal members 47, for example. When the first elastic members 61 are arranged to support the display 22 from four directions as in the embodiment, the position of the display 22 along the first and second directions is fixed only by placing the display 22 on the mask member 23. Specifically, screwing steps or the like can be omitted.

Since there are the elastic members 62 and 63 interposed between the display 22 and the second cover member 24, the position of the display 22 can be fixed along the thickness direction of the display unit 3, without using fixing members such as screws. These points contribute to improvement in assemblability of the portable computer 1.

The present invention is not limited to the portable computer 1 according to the embodiment described above. For example, the touch pad 9 may be contained inside the first housing 4 and exposed to the outside through an opening provided in the touch pad placing portion 13. The touch pad 9 which is placed on the bottom wall 13b of the touch pad placing portion 13 as in the above embodiment has an advantage of improvement of assemblability, since the mounting direction of the touch pad 9 is the same as the mounting direction of the keyboard 8.

The mounting components of the invention are not limited to the keyboard 8 and the touch pad 9, but various input devices and output devices such as a power switch and a speaker also correspond to the mounting components. Electronic apparatuses to which the present invention is applicable are not limited to portable computers.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of manufacturing an electronic apparatus, the electronic apparatus including a first housing to which a mounting component is attached, a second housing containing a display, and a hinge portion which rotatably connects the second housing to the first housing, comprising:
preparing a subassembly product formed by connecting a cover member, which is to form part of the first housing and to which the mounting component is to be mounted, with a mask member, which is to form part of the second housing and is provided with an opening portion to expose a display screen of the display to outside, by the hinge portion; and
mounting the mounting component on the cover member through the opening portion of the mask member, in a state where the subassembly product is folded such that the mask member is superposed on the cover member.

2. A method according to claim 1, further comprising:
mounting the display on the mask member, after the mounting component is mounted on the cover member.

3. A method according to claim 2, wherein
the mounting of the display is performed in the state where the subassembly product is folded such that the mask member is superposed on the cover member.

4. A method according to claim 3, wherein
the electronic apparatus includes another cover member which forms part of the second housing and faces the display from a side distant from the mask member, and
the method includes engaging said another cover member with the mask member in the state where the subassembly product is folded such that the mask member is superposed on the cover member of the first housing, after the mounting component and the display are mounted.

5. A method according to claim 1, wherein
the mounting component is a keyboard,
the electronic apparatus includes a keyboard holder which fixes one end portion of the keyboard to the cover member of the first housing, and
the method includes attaching the keyboard holder to the cover member of the first housing through the opening portion of the mask member, in the state where the subassembly product is folded such that the mask member is superposed on the cover member of the first housing.

6. A method according to claim 5, wherein
the electronic apparatus includes a touch pad to be attached to the cover member of the first housing, and
the method includes mounting the touch pad on the cover member of the first housing through the opening portion of the mask member, in the state where the subassembly product is folded such that the mask member is superposed on the cover member of the first housing.

7. An electronic apparatus comprising:
a first housing;
a second housing;
a hinge portion which rotatably connects the second housing to the first housing;
a mounting component attached to the first housing; and
a display which is contained in the second housing and includes a display screen,
wherein
the first housing includes a first cover member to which the mounting component is attached,
the second housing includes a mask member provided with an opening portion which exposes the display screen to outside, and a second cover member which faces the display from a side distant from the mask member and is engaged with the mask member,
the hinge portion connects the mask member to the first cover member,
the display and the second cover member are detachable from the mask member; and
the opening portion of the mask member is larger than an outer shape of the mounting component.

8. An electronic apparatus according to claim 7, wherein
the hinge portion includes a hinge shaft which is provided between the first housing and the second housing, and a support member which is connected to the hinge shaft, extends into the second housing and is attached to the mask member, and
the support member extends from one end portion of the mask member to the other end portion of the mask member along a direction perpendicular to an axial direction of the hinge shaft.

9. An electronic apparatus according to claim 8, further comprising:
another hinge portion having the same structure as that of the hinge portion,
wherein
the hinge portions are provided distant from each other along the axial direction of the hinge shaft,
an edge portion of the mask member, which is most distant from the hinge shafts, is provided with a rib extending along the axial direction of the hinge shaft, and the rib extends between the support members of the hinge portions.

10. An electronic apparatus according to claim 7, further comprising:
an elastic member interposed between the display and the second cover member,
wherein the elastic member presses the display toward the mask member.

11. A subassembly product forming part of an electronic apparatus, the electronic apparatus including a first housing and a second housing which contains a display, the display including a display screen, comprising:
a cover member which is to form part of the first housing and is provided with a placing portion, to which a mounting component is to be placed;
a mask member which is to form part of the second housing, includes an opening portion to expose the display screen to outside, and includes an area to which the display is to be mounted, the area being opened to outside; and
a hinge portion which rotatably connects the mask member to the cover member,
wherein a whole area of the placing portion is exposed to outside through the opening portion of the mask member, in a state where the mask member is superposed on the cover member.
